(19) United States
(12) Patent Application Publication
(10) Pub. No.: US 2026/0235823 A1
(43) Pub. Date: Aug. 13, 2026

(54) PHOTONIC PACKAGE, PHOTONIC SYSTEM AND METHOD OF MANUFACTURING PHOTONIC SYSTEM

(71) Applicant: Taiwan Semiconductor Manufacturing Company, Ltd., Hsinchu (TW)

(72) Inventors: Ming-Fa CHEN, Taichung City (TW); Chia-Hung Liu, Hsinchu City (TW); Yu-Siang Lin, Hsinchu City (TW)

(73) Assignee: Taiwan Semiconductor Manufacturing Company, Ltd., Hsinchu (TW)

(21) Appl. No.: 19/050,118

(22) Filed: Feb. 11, 2025

(51) Int. Cl. G02B 6/42; H01L 23/00; H01L 23/538; H01L 25/00; H01L 25/16

(52) U.S. Cl. CPC G02B 6/4214; H10W 70/611; H10W 90/00; H10W 90/401; H10W 90/794

(57) ABSTRACT

A photonic package includes a photonic die and an electronic die disposed over a front side of the photonic die. The photonic die includes an optical coupler and a recess extending from a back side of the photonic die toward the front side of the photonic die, wherein the recess includes a first facet at an end of the optical coupler and a second facet opposite to the first facet and non-parallel to the first facet for reflecting light to or from the optical coupler.

### BACKGROUND

Electrical signaling and processing are one of techniques for signal transmission and processing. Optical signaling and processing have been used in increasingly more applications in recent years, particularly due to the use of optical fiber-related applications for signal transmission.

Optical signaling and processing are typically combined with electrical signaling and processing to provide full-fledged applications. For example, optical fibers may be used for long-range signal transmission, and electrical signals may be used for short-range signal transmission as well as processing and controlling. Accordingly, devices integrating optical components and electrical components are formed for the conversion between optical signals and electrical signals, as well as the processing of optical signals and electrical signals. Packages thus may include both optical (photonic) dies including optical devices and electronic dies including electronic devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 to FIG. 16 illustrate the cross-sectional views of intermediate stages in the formation of a photonic package in accordance with some embodiments.

FIG. 17 illustrates a cross-sectional view of a photonic system in accordance with some embodiments.

FIG. 18 illustrates a cross-sectional view of an intermediate stage of forming a photonic package in accordance with some embodiments.

FIG. 19 illustrates a cross-sectional view of an intermediate stage of forming a photonic package in accordance with some embodiments.

FIG. 20 illustrates a cross-sectional view of an intermediate stage of forming a photonic package in accordance with some embodiments.

FIG. 21 illustrates a process flow for forming a photonic package in accordance with some embodiments.

FIG. 22 illustrates a process flow for forming a recess in a photonic package in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In this disclosure, various aspects of a package and the formation thereof are described. Three-dimensional (3D) packages including both optical devices and electrical devices, and the method of forming the same are provided, in accordance with some embodiments. In particular, photonic packages including a recess formed corresponding to an optical coupler of a photonic die, wherein the recess includes a vertical side surface adjacent to the optical coupler and a curvy side surface opposite to the vertical side surface for reflecting light to or from the optical coupler. Optical signals generated by a photonic component within the photonic package, such as a laser diode, can be transmitted to an optical fiber through the optical coupler and be reflected upward to the backside of the photonic die by the curvy side surface of the recess. Accordingly, the optical fiber can be mounted on the backside of the photonic die to be optically coupled with the photonic package instead of edge mounted on a side surface of the photonic package, so that a wafer-level optical testing can be realized and number of input/output ports (i.e., numbers of optical couplers and/or waveguides). The intermediate stages of forming the packages are illustrated, in accordance with some embodiments. Some variations of some embodiments are discussed. Throughout the various views and illustrative embodiments, like reference numbers are used to designate like elements.

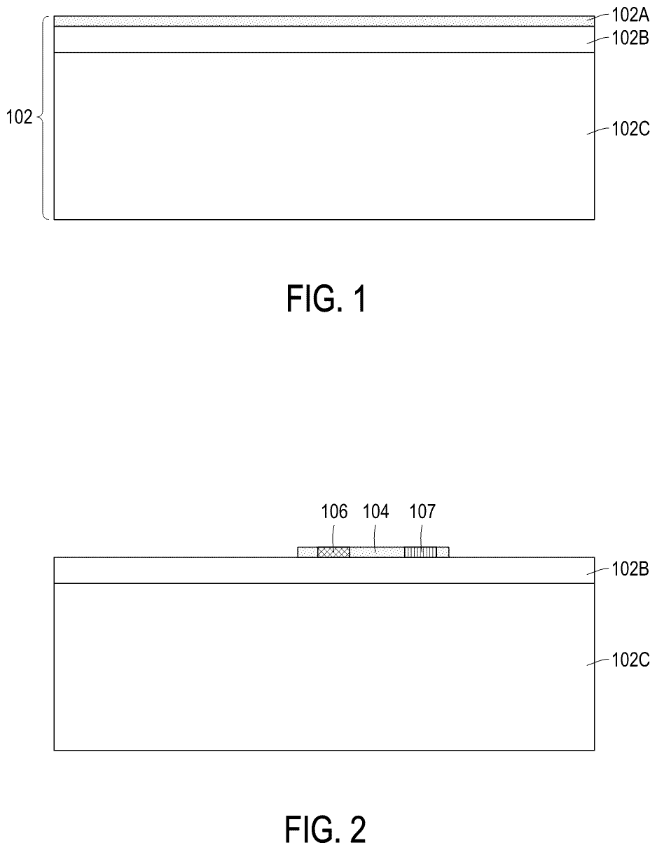

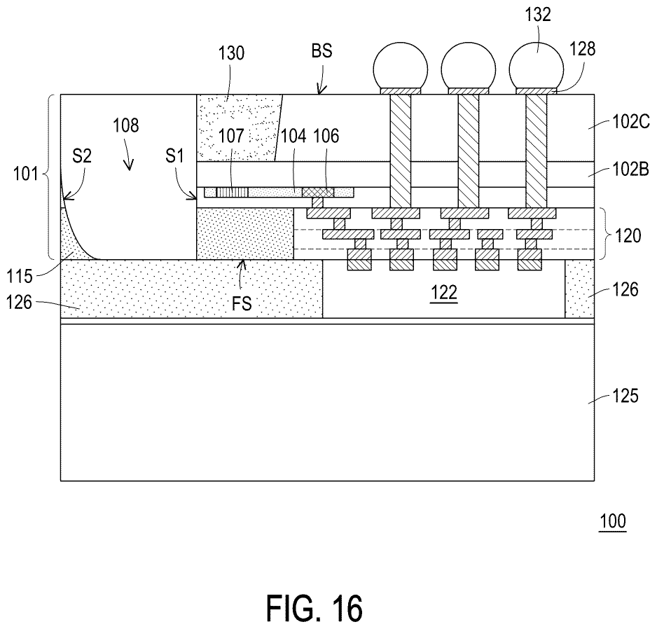

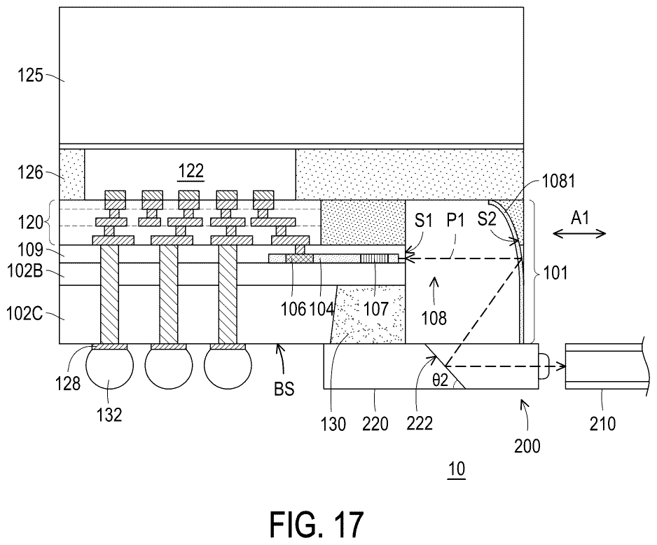

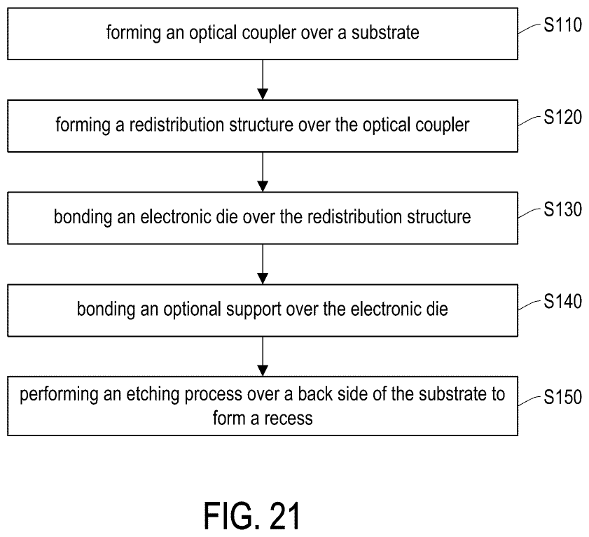

FIG. 1 to FIG. 16 illustrate the cross-sectional views of intermediate stages in the formation of a photonic package 100 (see FIG. 16) in accordance with some embodiments. FIG. 21 illustrates a process flow for forming a photonic package in accordance with some embodiments. In some embodiments, the photonic package 100 acts as an input/output (I/O) interface between optical signals and electrical signals in a photonic system. For example, one or more photonic packages 100 may be used in a photonic system such as the photonic system 10 (see FIG. 17), the like, or another photonic system.

Referring first to FIG. 1, a substrate 102 is provided. The substrate 102 includes a buried oxide (“BOX”) substrate in accordance with some embodiments. In the present embodiment, the substrate 102 includes an oxide layer 102B formed over a substrate 102C, and a silicon layer 102A formed over the oxide layer 102B. The substrate 102C may be, for example, a material such as a glass, ceramic, dielectric, a semiconductor, the like, or a combination thereof. In some embodiments, the substrate 102C may be a semiconductor substrate, such as a bulk semiconductor or the like, which may be doped (e.g., with a p-type or an n-type dopant) or undoped. The substrate 102C may be a wafer, such as a silicon wafer (e.g., a 12-inch silicon wafer). Other substrates, such as a multi-layered or gradient substrate may also be used. In some embodiments, the semiconductor material of the substrate 102C may include silicon; germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. The oxide layer 102B may be, for example, a silicon oxide or the like. In some embodiments, the oxide layer 102B may have a thickness between about 0.5 μm and about 4 μm. The silicon layer 102A may have a thickness between about 0.1 μm and about 1.5 μm, in some embodiments. The BOX substrate 102 may be referred to as having a front side or front surface (e.g., the side facing upwards in FIG. 1), and a back side or back surface (e.g., the side facing downwards in FIG. 1).

Referring to FIG. 2, the silicon layer 102A is patterned to form silicon regions for at least one waveguide 104, at least one photonic component 106, and/or at least one optical optical couplers 107, in accordance with some embodiments. The respective process is illustrated as process S110 in the process flow shown in FIG. 21. The silicon layer 102A may be patterned using suitable photolithography and etching techniques. For example, a hardmask layer (e.g., a nitride layer or other dielectric material, not shown in FIG. 2) may be formed over the silicon layer 102A and patterned, in some embodiments. The pattern of the hardmask layer may then be transferred to the silicon layer 102A using one or more etching techniques, such as dry etching and/or wet etching techniques. For example, the silicon layer 102A may be etched to form recesses defining the waveguides 104, with sidewalls of the remaining unrecessed portions defining sidewalls of the waveguides 104. In some embodiments, more than one photolithography and etching sequence may be used in order to pattern the silicon layer 102A. One waveguide 104 or multiple waveguides 104 may be patterned from the silicon layer 102A. If multiple waveguides 104 are formed, the multiple waveguides 104 may be individual separate waveguides 104 or connected as a single continuous structure. In some embodiments, one or more of the waveguides 104 form a continuous loop. Other configurations or arrangements of waveguides 104, the photonic components 106, or the optical couplers 107 are possible. In some cases, the waveguides 104, the photonic components 106, and the optical couplers 107 may be collectively referred to as “the photonic layer.”

The photonic components 106 may be integrated with the waveguides 104, and may be formed with the silicon waveguides 104. The photonic components 106 may be optically coupled to the waveguides 104 to interact with optical signals within the waveguides 104. The photonic components 106 may include, for example, photodetectors and/or modulators. For example, a photodetector may be optically coupled to the waveguides 104 to detect optical signals within the waveguides 104 and generate electrical signals corresponding to the optical signals. A modulator may be optically coupled to the waveguides 104 to receive electrical signals and generate corresponding optical signals within the waveguides 104 by modulating optical power within the waveguides 104. In this manner, the photonic components 106 facilitate the input/output (I/O) of optical signals to and from the waveguides 104. In other embodiments, the photonic components may include other active or passive components, such as laser diodes, optical signal splitters, or other types of photonic structures or devices. Optical power may be provided to the waveguides 104 by, for example, an optical fiber 210 (see FIG. 17) coupled to an external light source, or the optical power may be generated by a photonic component within the photonic package 100 such as a laser diode (not shown in the figures).

In some embodiments, the photodetectors may be formed by, for example, partially etching regions of the waveguides 104 and growing an epitaxial material on the remaining silicon of the etched regions. The waveguides 104 may be etched using acceptable photolithography and etching techniques. The epitaxial material may comprise, for example, a semiconductor material such as germanium (Ge), which may be doped or undoped. In some embodiments, an implantation process may be performed to introduce dopants within the silicon of the etched regions as part of the formation of the photodetectors. The silicon of the etched regions may be doped with p-type dopants, n-type dopants, or a combination. In some embodiments, the modulators may be formed by, for example, partially etching regions of the waveguides 104 and then implanting appropriate dopants within the remaining silicon of the etched regions. The waveguides 104 may be etched using acceptable photolithography and etching techniques. In some embodiments, the etched regions used for the photodetectors and the etched regions used for the modulators may be formed using one or more of the same photolithography or etching steps. The silicon of the etched regions may be doped with p-type dopants, n-type dopants, or a combination. In some embodiments, the etched regions used for the photodetectors and the etched regions used for the modulators may be implanted using one or more of the same implantation steps.

In some embodiments, one or more optical couplers 107 may be integrated with the waveguides 104, and may be formed with the waveguides 104. The optical couplers 107 are photonic structures that allow optical signals and/or optical power to be transferred between the waveguides 104 and a photonic component such as an optical fiber 210 or a waveguide of another photonic system. The optical couplers 107 may include one or more edge couplers, which may be continuous with the waveguides 104 and may be formed in the same processing steps as the waveguides 104 or other photonic components 106 as shown in FIG. 2. The edge couplers allow optical signals and/or optical power to be transferred between the waveguide 104 and a photonic component that is “edge-mounted” near a sidewall of the photonic package 100.

The photonic package may include a single optical coupler 107, multiple optical couplers 107, or multiple types of optical couplers 107, in some embodiments. The optical couplers 107 may be formed using acceptable photolithography and etching techniques. In some embodiments, the optical couplers 107 are formed using the same photolithography or etching steps as the waveguides 104 and/or the photonic components 106. In other embodiments, the optical couplers 107 are formed after the waveguides 104 and/or the photonic components 106 are formed.

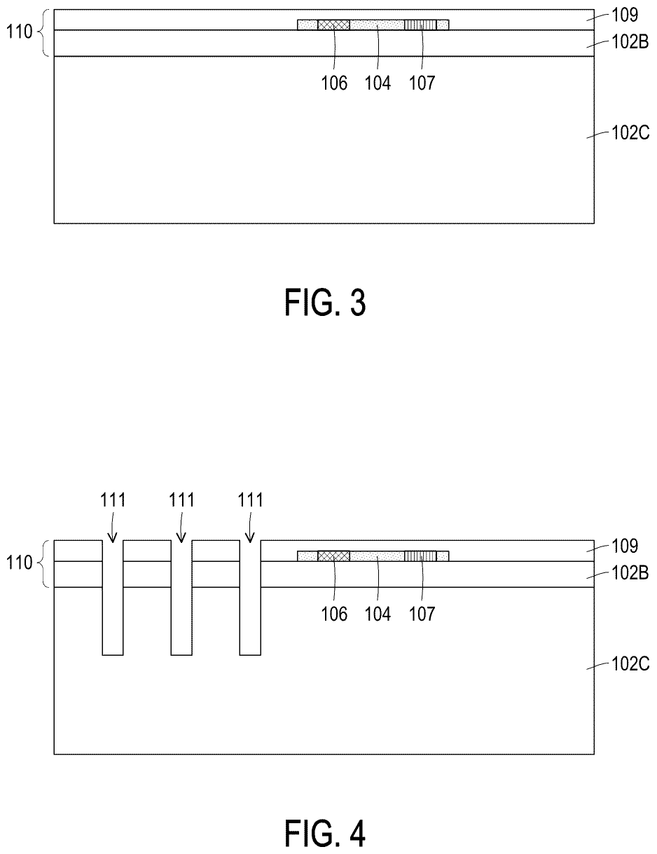

With now reference to FIG. 3, a dielectric layer 109 is formed on the front side of the substrate 102 to form a photonic routing structure 110, in accordance with some embodiments. The dielectric layer 109 is formed over the waveguides 104, the photonic components 106, the optical couplers 107, and the oxide layer 102B. The dielectric layer 109 may be formed of one or more layers of silicon oxide, silicon nitride, a combination thereof, or the like, and may be formed by chemical vapor deposition (CVD), physical vapor deposition (PVD), atomic layer deposition (ALD), a spin-on-dielectric process, the like, or a combination thereof. In some embodiments, the dielectric layer 109 may be formed by a high density plasma chemical vapor deposition (HDP-CVD), a flowable CVD (FCVD) (e.g., a CVD-based material deposition in a remote plasma system and post curing to make it convert to another material, such as an oxide), the like, or a combination thereof. Other dielectric materials formed by any acceptable process may be used. In some embodiments, the dielectric layer 109 is then planarized using a planarization process such as a CMP process, a grinding process, or the like. The dielectric layer 109 may be formed having a thickness over the oxide layer 102B between about 50 nm and about 500 nm, or may be formed having a thickness over the waveguides 104 between about 10 nm and about 200 nm, in some embodiments.

Due to the difference in refractive indices of the materials of the waveguides 104 and dielectric layer 109, the waveguides 104 have high internal reflections such that light is substantially confined within the waveguides 104, depending on the wavelength of the light and the refractive indices of the respective materials. In an embodiment, the refractive index of the material of the waveguides 104 is higher than the refractive index of the material of the dielectric layer 109. For example, the waveguides 104 may include silicon, and the dielectric layer 109 may include silicon oxide and/or silicon nitride.

Referring to FIG. 4, a plurality of openings 111 are formed extending into the substrate 102C, in accordance with some embodiments. The openings 111 are formed extending through the dielectric layer 109 and the oxide layer 102B, and may extend partially into the substrate 102C. The openings 111 may be formed by acceptable photolithography and etching techniques, such as by forming and patterning a photoresist and then performing an etching process using the patterned photoresist as an etching mask. The etching process may include, for example, a dry etching process and/or a wet etching process.

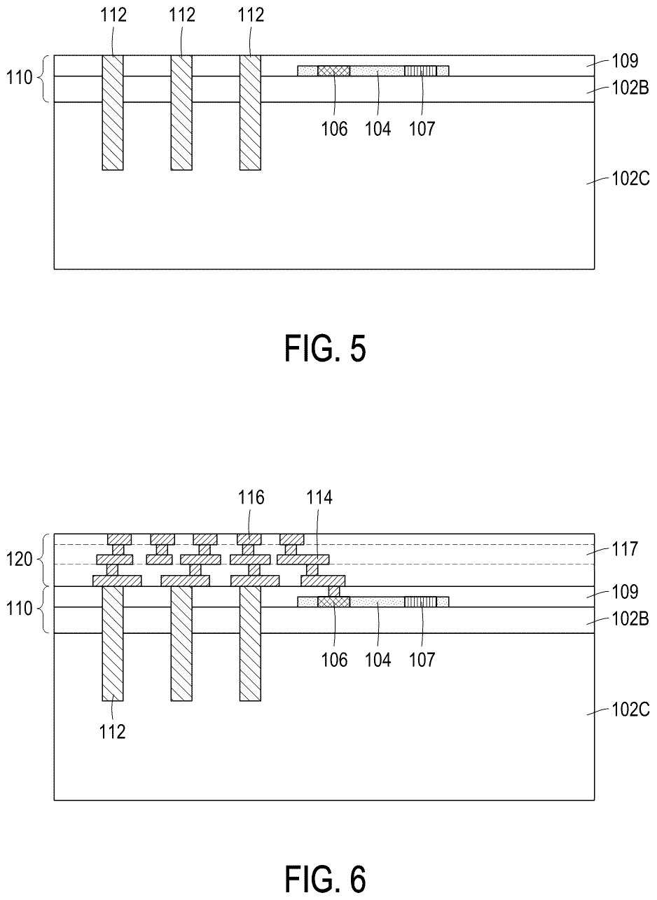

Then, referring to FIG. 5, a conductive material is formed in the openings 111, thereby forming a plurality of vias 112, in accordance with some embodiments. In some embodiments, a liner (not shown), such as a diffusion barrier layer, an adhesion layer, or the like, may be formed in the openings 111 from TaN, Ta, TiN, Ti, CoW, or the like, and may be formed using suitable a deposition process such as ALD or the like. In some embodiments, a seed layer (not shown), which may include copper or a copper alloy may then be deposited in the openings 111. The conductive material of the vias 112 is formed in the openings 111 using, for example, ECP or electro-less plating. The conductive material may include, for example, a metal or a metal alloy such as copper, silver, gold, tungsten, cobalt, aluminum, or alloys thereof. A planarization process (e.g., a CMP process or a grinding process) may be performed to remove excess conductive material along the top surface of the dielectric layer 109, such that top surfaces of the vias 112 and the dielectric layer 109 are level.

FIG. 5 also shows the formation of contacts 113 that extend through the dielectric layer 109 and are electrically connected to the photonic components 106. The contacts 113 allow electrical power or electrical signals to be transmitted to the photonic components 106 and electrical signals to be transmitted from the photonic components 106. In this manner, the photonic components 106 may convert electrical signals (e.g., from an electronic die 122, see FIG. 9) into optical signals transmitted by the waveguides 104, and/or convert optical signals from the waveguides 104 into electrical signals (e.g., that may be received by an electronic die 122). The contacts 113 may be formed before or after formation of the vias 112, and the formation of the contacts 113 and the formation of the vias 112 may share some steps such as deposition of the conductive material and/or planarization. In some embodiments, the contact may be formed by a damascene process, e.g., single damascene, dual damascene, or the like. For example, in some embodiments, openings (not shown) for the contacts 113 are first formed in the dielectric layer 109 using acceptable photolithography and etching techniques. A conductive material may then be formed in the openings, forming the contacts 113. Excess conductive material may be removed using a CMP process or the like. The conductive material of the contacts 113 may be formed of a metal or a metal alloy including aluminum, copper, tungsten, or the like, which may be the same as that of the vias 112. The contacts 113 may be formed using other techniques or materials in other embodiments.

With now reference to FIG. 6, a redistribution structure 120 is formed over the dielectric layer 109 covering the optical coupler 107, in accordance with some embodiments. The respective process is illustrated as process S120 in the process flow shown in FIG. 21. The redistribution structure 120 includes dielectric layers 117 and conductive features 114 formed in the dielectric layers 117 that provide interconnections and electrical routing. For example, the redistribution structure 120 may connect the vias 112, the contacts 113, and/or overlying devices such as electronic dies 122 (see FIG. 9). The dielectric layers 117 may be, for example, insulating or passivating layers, and may comprise one or more materials similar to those described above for the dielectric layer 109, such as a silicon oxide or a silicon nitride, or may comprise a different material. The dielectric layers 117 and the dielectric layer 109 may be transparent or nearly transparent to light within the same range of wavelengths. The dielectric layers 117 may be formed using a technique similar to those described above for the dielectric layer 109 or using a different technique. The conductive features 114 may include conductive lines and vias, and may be formed by a damascene process, e.g., single damascene, dual damascene, or the like. As shown in FIG. 6, conductive pads 116 are formed in the topmost layer of the dielectric layers 117. A planarization process (e.g., a CMP process or the like) may be performed after forming the conductive pads 116 such that surfaces of the conductive pads 116 and the topmost dielectric layer 117 are substantially coplanar. The redistribution structure 120 may include more or fewer dielectric layers 117, conductive features 114, or conductive pads 116 than shown in FIG. 6. The redistribution structure 120 may be formed having a thickness between about 4 μm and about 6 μm, in some embodiments. Other thicknesses are possible.

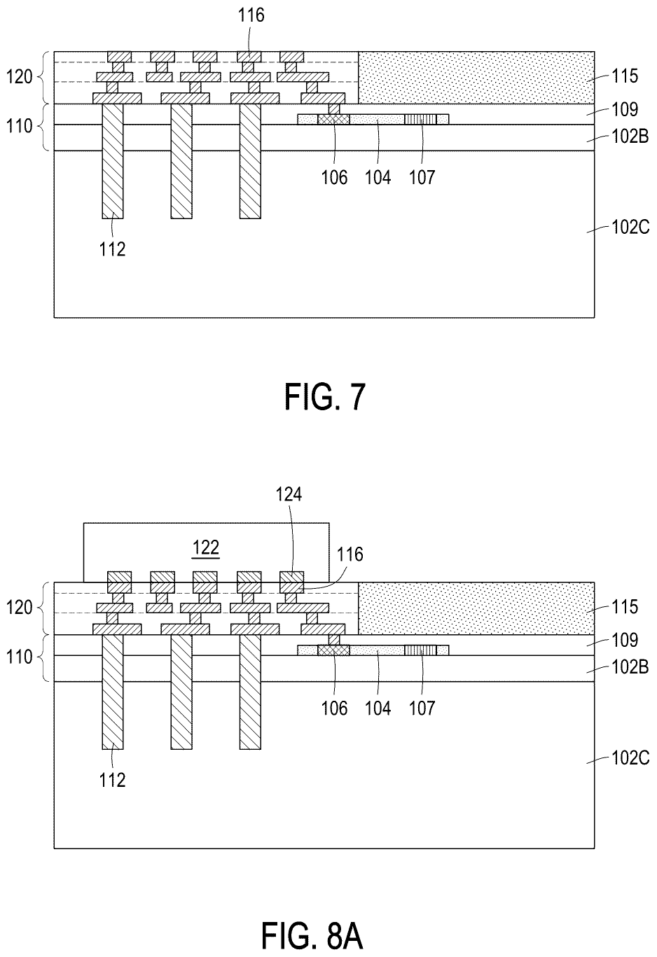

Then, referring to FIG. 7, a portion of the redistribution structure 120 is removed and replaced by a dielectric layer 115, in accordance with some embodiments. The portion of the redistribution structure 120 may be removed, for example, using acceptable photolithography and etching techniques, such as by forming and patterning a photoresist and then performing an etching process to remove the dielectric layers 117 using the patterned photoresist as an etching mask. The etching process may include, for example, a dry etching process and/or a wet etching process. The dielectric layer 115 may then be deposited to replace the removed portion of the redistribution structure 120. The dielectric layer 115 may comprise one or more materials similar to those described above for the dielectric layer 109, such as a silicon oxide or a silicon nitride, or may comprise a different material. In some embodiments, the dielectric layer 115 and the dielectric layer 109 may be transparent or nearly transparent to light within the same range of wavelengths. The dielectric layer 115 may be formed using a technique similar to those described above for the dielectric layer 109 or using a different technique. In some embodiments, a planarization process (e.g., a CMP or grinding process) is used to remove excess material of the dielectric layer 115. The planarization process may also expose the conductive pads 116. After performing the planarization process, the dielectric layer 115, the topmost dielectric layer 117, and/or the conductive pads 116 may have substantially level surfaces. In some cases, replacing a portion of the redistribution structure 120 with the dielectric layer 115 can improve the optical confinement within the waveguides 104 beneath the dielectric layer 115. In other embodiments, the redistribution structure 120 is not etched and the dielectric layer 115 is not formed.

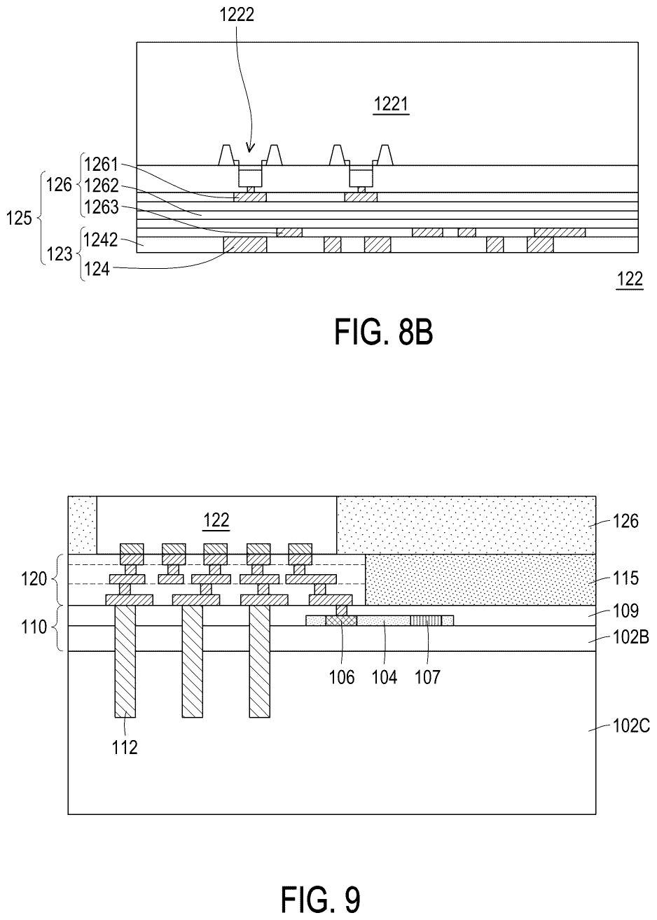

Then, referring to FIG. 8A, at least one electronic die 122 is bonded over the redistribution structure 120. The respective process is illustrated as process S130 in the process flow shown in FIG. 21. One or more electronic dies 122 are bonded to the redistribution structure 120, in accordance with some embodiments. The electronic dies 122 may be, for example, semiconductor devices, dies, or chips that communicate with the photonic components 106 using electrical signals. One electronic die 122 is shown in FIG. 8A, but a photonic package may include two or more electronic dies 122 in other embodiments. In some cases, multiple electronic dies 122 may be incorporated into a single photonic package 100 in order to reduce processing cost. The electronic die 122 may include die connectors 124, which may be, for example, conductive pads, conductive pillars, or the like. In some embodiments, the electronic die 122 may have a thickness between about 10 μm and about 35 μm. Other thicknesses are possible. It is noted that the electronic die 122 is depicted as a blank block for simplicity purposes. An exemplary electronic die 122 is illustrated with more detail in FIG. 8B hereinafter, but the disclosure is not limited thereto.

FIG. 8B illustrates a cross-sectional view of the electronic die of the photonic system in accordance with some embodiments. Referring to FIG. 8A and FIG. 8B, in some embodiments, the electronic die 122 may include integrated circuits for interfacing with the photonic components 106, such as circuits for controlling the operation of the photonic components 106. For example, the electronic die 122 may include controllers, drivers, transimpedance amplifiers (TIAs), the like, or combinations thereof. The electronic die 122 may also include a CPU, in some embodiments. In some embodiments, the electronic die 122 includes circuits for processing electrical signals received from photonic components 106, such as for processing electrical signals received from a photonic component 106 comprising a photodetector. The electronic die 122 may control high-frequency signaling of the photonic components 106 according to electrical signals (digital or analog) received from another device or die, in some embodiments. In some embodiments, the electronic die 122 may be an electronic integrated circuit (EIC) or the like that provides Serializer/Deserializer (SerDes) functionality. In this manner, the electronic die 122 may act as part of an I/O interface between optical signals and electrical signals within a photonic package 100, and the photonic package 100 described herein could be a considered system-on-chip (SoC) or a system-on-integrated-circuit (SoIC) device.

Referring to FIG. 8B, the electronic die 122 includes a semiconductor substrate 1221, which may be made of silicon or other semiconductor materials. Alternatively or additionally, the semiconductor substrate 1221 may include other elementary semiconductor materials such as germanium. In some embodiments, the semiconductor substrate 1221 is made of a compound semiconductor such as silicon carbide, gallium arsenic, indium arsenide or indium phosphide. In some embodiments, the semiconductor substrate 1221 is made of an alloy semiconductor such as silicon germanium, silicon germanium carbide, gallium arsenic phosphide, or gallium indium phosphide. In some embodiments, the semiconductor substrate 1221 includes an epitaxial layer. For example, the semiconductor substrate 1221 has an epitaxial layer overlying a bulk semiconductor.

In some embodiments, a device regions 1222 are formed on the semiconductor substrate 1221 in a front-end-of-line (FEOL) process in some embodiments. One of the device regions 1222 includes a gate structure, source/drain regions, and isolation structures, such as shallow trench isolation (STI) structures (not shown). The device regions 1222 shown in FIG. 8B are merely examples, and other structures may be formed in the device regions 1222. In the device regions 1222, various N-type metal-oxide semiconductor (NMOS) and/or P-type metal-oxide semiconductor (PMOS) devices, such as transistors or memories and the like, may be formed and interconnected to perform one or more functions. Other devices, such as capacitors, resistors, diodes, photodiodes, fuses and the like may also be formed on the semiconductor substrate 1221. The functions of the devices may include memory, processors, sensors, amplifiers, power distribution, input/output circuitry, or the like.

In some embodiments, a metallization structure 125 is formed in a back-end-of-line (BEOL) process. The metallization structure 125 includes an interconnect structure 126. In some embodiments, the interconnect structure 126 is formed over the semiconductor substrate 1221, e.g., over the device regions 1222. In some embodiments, the interconnect structure 126 includes plugs 1261 and conductive lines 1263. The plugs 1261 and the conductive lines 1263 are embedded in an insulating material 1262. The plugs 1261 and the conductive lines 1263 may be made of tungsten (W), copper (Cu), copper alloys, aluminum (Al), aluminum alloys, or a combination thereof. In some embodiments, the insulating material 1262 is made of silicon oxide, silicon oxynitride, silicon nitride, low dielectric constant (low-k) materials or a combination thereof. In some embodiments, the insulating material 1262 may be a single layer or multiple layers.

In some embodiments, a barrier layer (not shown) may be formed between the plugs 1261 and the insulating material 1262 or between the conductive lines 1263 and the insulating material 1262 to prevent the material of the plugs 1261 or the conductive lines 1263 from migrating to the device regions 1222. A material of the barrier layer includes tantalum, tantalum nitride, titanium, titanium nitride, cobalt-tungsten (CoW) or a combination thereof, for example. A method of forming the barrier layer includes, for example, physically vapor deposition (PVD) process.

In some embodiments, the metallization structure 125 further includes a bonding layer 123. The bonding layer 123 is formed over the interconnect structure 126. The bonding layer 123 includes die connectors 124 (e.g. pads) embedded in a dielectric layer 1242. The die connectors 124 are connected to the interconnect structure 126. The die connectors 124 may be made of conductive materials such as copper (Cu), copper alloy, aluminum (Al), aluminum alloy, or combinations thereof. Other applicable materials may be included for the die connectors 124. In some embodiments, the dielectric layer 1242 is made of silicon oxide, silicon nitride, polymer or a combination thereof.

Referring to FIG. 8A and FIG. 8B, in some embodiments, the electronic die 122 is bonded to the redistribution structure 120 via the bonding layer 123 by dielectric-to-dielectric bonding and/or metal-to-metal bonding (e.g., direct bonding, fusion bonding, oxide-to-oxide bonding, hybrid bonding, or the like). In such embodiments, covalent bonds may be formed between oxide layers, such as the topmost dielectric layer of the redistribution structure 120 and surface dielectric layers (e.g., dielectric layer 1242) of the electronic die 122. During the bonding, metal bonding may also occur between the die connectors 124 of the electronic die 122 and the conductive pads 116 of the redistribution structure 120.

In some embodiments, before performing the bonding process, a surface treatment is performed on the electronic die 122. In some embodiments, the top surfaces of the redistribution structure 120 and/or the electronic die 122 may first be activated utilizing, for example, a dry treatment, a wet treatment, a plasma treatment, exposure to an inert gas, exposure to H₂, exposure to N₂, exposure to O₂, the like, or combinations thereof. However, any suitable activation process may be utilized. After the activation process, the redistribution structure 120 and/or the electronic die 122 may be cleaned using, e.g., a chemical rinse. The electronic die 122 is then aligned with the redistribution structure 120 and placed into physical contact with the redistribution structure 120. The electronic die 122 may be placed on the redistribution structure 120 using a pick and place process, for example. The redistribution structure 120 and the electronic die 122 may then be subjected to a thermal treatment and/or pressed against each other (e.g., by applying contact pressure) to bond the redistribution structure 120 and the electronic die 122. For example, the redistribution structure 120 and the electronic die 122 may be subjected to a pressure of about 200 kPa or less, and to a temperature between about 200° C. and about 400° C. The redistribution structure 120 and the electronic die 122 may then be subjected to a temperature at or above the eutectic point of the material of the conductive pads 116 and the die connectors 124 (e.g., between about 150° C. and about 650° C.) to fuse the conductive pads 116 and the die connectors 124. In this manner, the dielectric-to-dielectric bonding and/or metal-to-metal bonding of the redistribution structure 120 and the electronic die 122 forms a bonded structure. In some embodiments, the bonded structure is baked, annealed, pressed, or otherwise treated to strengthen or finalize the bonds.

In FIG. 9, a dielectric material 126 is formed over the electronic die 122 and the redistribution structure 120, in accordance with some embodiments. The dielectric material 126 may be formed of silicon oxide, silicon nitride, a polymer, the like, or a combination thereof. The dielectric material 126 may be formed by CVD, PVD, ALD, a spin-on-dielectric process, the like, or a combination thereof. In some embodiments, the dielectric material 126 may be formed by HDP-CVD, FCVD, the like, or a combination thereof. The dielectric material 126 may be a gap-fill material in some embodiments, which may include one or more of the example materials above. Other dielectric materials formed by any acceptable process may be used. The dielectric material 126 may be planarized using a planarization process such as a CMP process, a grinding process, or the like. In some embodiments, the planarization process may expose the electronic die 122 such that a surface of the electronic die 122 and a surface of the dielectric material 126 are coplanar.

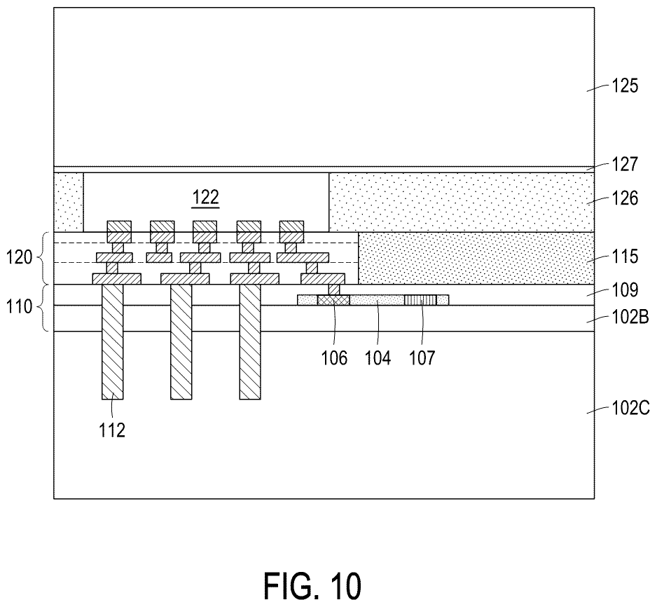

Then, referring to FIG. 10, an optional support 125 is bonded over the electronic die 122. The respective process is illustrated as process S140 in the process flow shown in FIG. 21. In the embodiment, the optional support 125 is attached to the resulting structure shown in FIG. 9, in accordance with some embodiments. The optional support 125 is a rigid structure that is attached to the structure in order to provide structural or mechanical stability. The use of an optional support 125 can reduce warping or bending, which can improve the performance of the optical structures such as the waveguides 104 or photonic components 106. The optional support 125 may include one or more materials such as silicon (e.g., a silicon wafer, bulk silicon, or the like), a silicon oxide, a metal, an organic core material, the like, or another type of material. The optional support 125 may be attached to the structure (e.g., to the dielectric material 126 and/or the electronic dies 122) using an adhesive layer 127, as shown in FIG. 10, or the optional support 125 may be attached using direct bonding or another suitable technique. In some embodiments, the optional support 125 may have a thickness between about 500 μm and about 700 μm. The optional support 125 may also have lateral dimensions (e.g., length, width, and/or area) that are greater than, about the same as, or smaller than those of the structure. In other embodiments, the optional support 125 is attached at a later process step during the manufacturing the photonic package than shown.

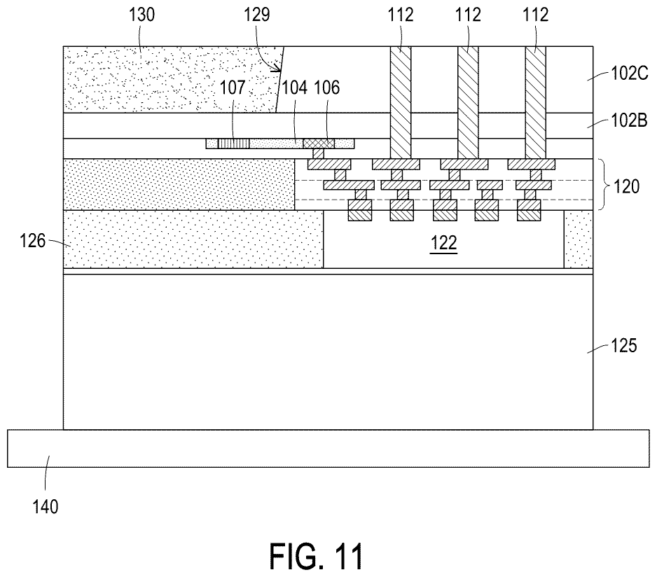

Referring to FIG. 11, the resulting structure shown in FIG. 10 is then flipped over and attached to a carrier 140, in accordance with some embodiments. The carrier 140 may be, for example, a wafer (e.g., a silicon wafer), a panel, a glass substrate, a ceramic substrate, or the like. The structure may be attached to the carrier 140 using, for example, an adhesive or a release layer (not shown). The back side of the substrate 102C is then thinned to expose the vias 112, in accordance with some embodiments. Accordingly, a plurality of through vias 112 extending through the substrate 102C and electrically connected to the electronic die 122 are formed. The substrate 102C may be thinned by a CMP process, a mechanical grinding, an etching process, the like, or a combination thereof.

In FIG. 11, a portion of the substrate 102C is removed to form a cavity 129 that exposes the oxide layer 102B, in accordance with some embodiments. The cavity 129 may extend over the waveguide 104 and over the optical coupler 107, and may extend to an edge of the photonic package, as shown in FIG. 11. In some embodiments, more than one cavity 129 is formed. The cavity 129 may be formed using suitable photolithography and etching techniques. For example, in some embodiments, a photoresist may be formed over the structure and patterned, wherein the pattern corresponds to the cavity 129. The substrate 102C may be etched using the patterned photoresist as an etching mask. The etching may be performed using one or more suitable techniques, such as a wet etching process, a dry etching process, or a combination thereof. In some embodiments, the etching may be selective such that the substrate 102C is removed without significant etching of the oxide layer 102B. For example, the etching may be performed using HNO₃, HF, CH₃COOH, the like, or combinations thereof. Other etching techniques are possible. In some embodiments, the cavity 129 may have a depth that is in the range of about 6 μm to about 25 μm, though other depths are possible. In some embodiments, a sidewall of the cavity 129 is sloped or faceted, such as shown in FIG. 11, but in other embodiments, the cavity 129 may have a vertical sidewall or a sidewall with a different slope than shown.

In FIG. 11, the cavity 129 is filled with a dielectric layer 130, in accordance with some embodiments. The dielectric layer 130 may include one or more materials similar to those described above for the dielectric layer 109 or the dielectric layer 115, such as a silicon oxide or the like. In some embodiments, the dielectric layer 130 may be transparent or nearly transparent to light within the same range of wavelengths. The dielectric layer 130 may be formed using a technique similar to those described above for the dielectric layer 109 or the dielectric layer 115, or may be formed using a different technique. For example, the dielectric layer 130 may be formed by CVD, PVD, HDP-CVD, FCVD, the like, or using a different technique. In some embodiments, a planarization process (e.g., a CMP, grinding process, and or etching process) is used to remove excess material of the dielectric layer 130. The planarization process may also expose the through vias 112. After performing the planarization process, the dielectric layer 130, the substrate 102C, and the through vias 112 may have substantially level surfaces.

In some cases, replacing a portion of the substrate 102C over the optical coupler 107 with the dielectric layer 130 can improve optical coupling from an optical fiber (e.g., the optical fiber 210 shown in FIG. 17) to the optical coupler 107. For example, the dielectric layer 130 may be a material that is more transparent to relevant wavelengths of light than the substrate 102C. For example, the dielectric layer 130 may be silicon oxide and the substrate 102C may be silicon, in some embodiments. In some cases, the material of the substrate 102C may reflect or absorb relevant wavelengths of light. By replacing the substrate 102C near the optical coupler 107 with the dielectric layer 130, less light from an optical fiber may be reflected or absorbed by the substrate 102C before reaching the coupler 107, and more light from the optical fiber may be coupled into the optical coupler 107. In this manner, optical loss may be reduced, and coupling efficiency between the optical coupler 107 and the optical fiber may be improved. Additionally, the formation of the dielectric layer 130 as described herein may avoid difficult process steps such as undercutting and refilling, and may allow for a photonic package with a more robust structure. In other embodiments, more than one cavities 129 filled with a dielectric layer 130 may be formed.

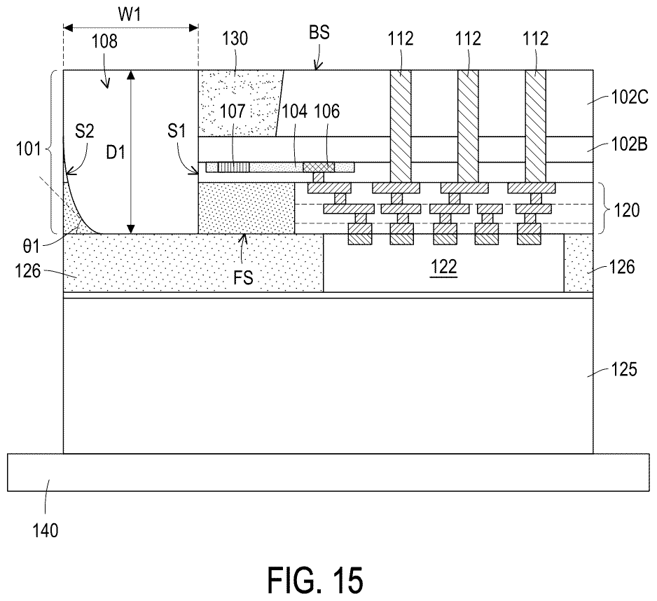

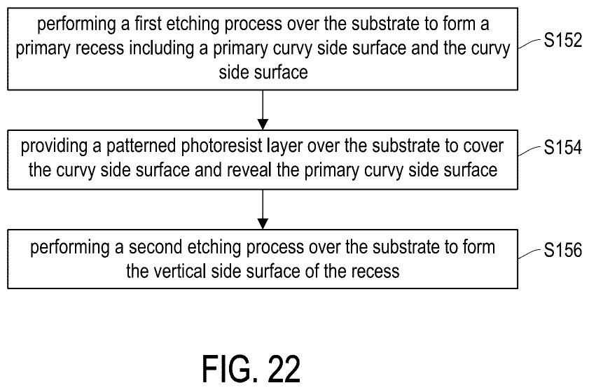

Then, an etching process is performed over a back side of the substrate 102C to form a recess 108 as shown in FIG. 15. The respective process is illustrated as process S150 in the process flow shown in FIG. 21, and the detailed exemplary embodiment of the etching process for forming the recess 108 in FIG. 15 is illustrated as steps S152 to S156 in the process flow shown in FIG. 22.

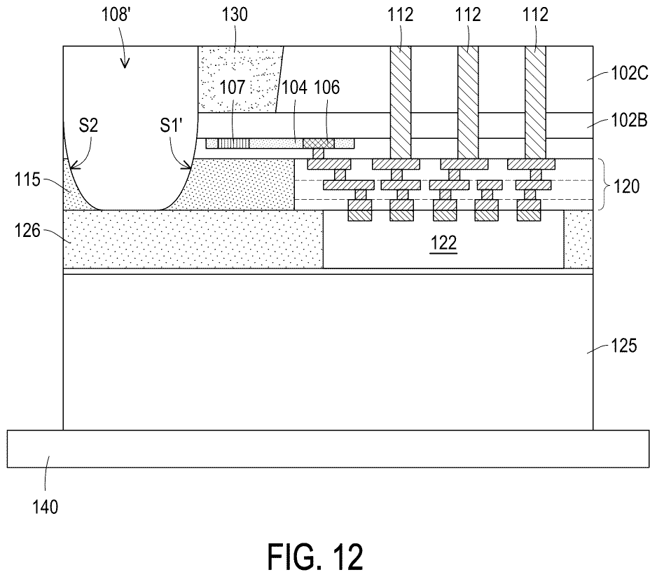

In accordance with some embodiments of the disclosure, referring first to FIG. 12, first etching process is performed over the back side of the substrate 102C to form a primary recess 108′. The respective process is illustrated as process S152 in the process flow shown in FIG. 22. The primary recess 108′ may extend through the substrate 102C, the oxide layer 102B, and into the redistribution structure 120. In the present embodiment, the primary recess 108′ extend through the dielectric layer 115 that replaces the removed portion of the redistribution structure 120 and reaches the top surface of the dielectric material 126 laterally encapsulate the electronic die 122. The dielectric material 115, 126 may include silicon oxide, silicon nitride, a polymer, the like, or a combination thereof. The primary recess 108′ may be formed by any acceptable etching technique such as a dry etch process, a wet etch process, or a combination thereof, or the like. The primary recess 108′ includes a primary curvy side surface S1′ adjacent to the optical coupler 107 and the curvy side surface S2 opposite to and the primary curvy side S1′. In the embodiment the curves of the two opposite side surfaces (i.e., the primary curvy side surface S1′ and the curvy side surface S2) of the primary recess 108′ are substantially symmetrical with each other.

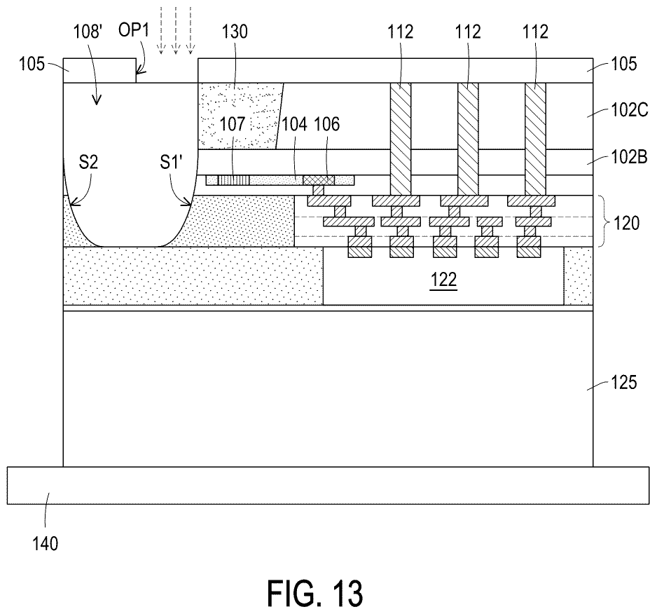

Next, referring to FIG. 13, a patterned photoresist layer 105 is provided over the back side of the substrate 102C. The respective process is illustrated as process S154 in the process flow shown in FIG. 22. In the embodiment, the patterned photoresist layer 105 covers the curvy side surface S2 and reveals the primary curvy side surface S1′. In other words, the patterned photoresist layer 105 includes an opening OP1 exposing the primary curvy side surface S1′ for a second etching process performed subsequently.

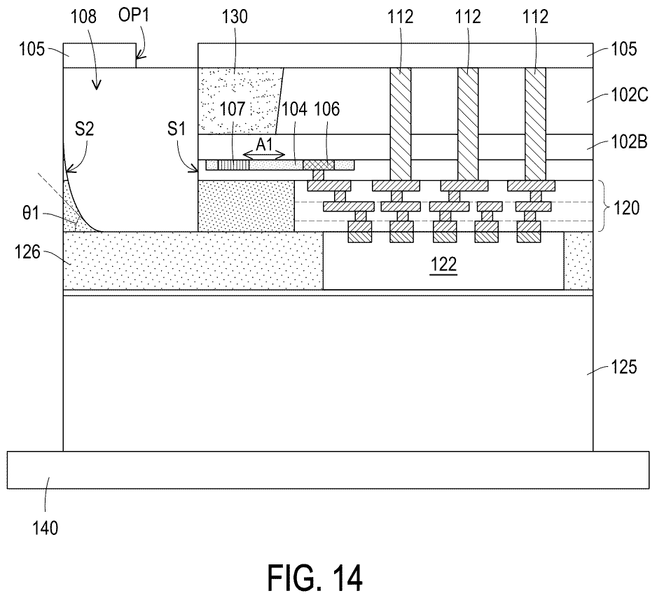

Then, referring to FIG. 13 and FIG. 14, a second etching process is performed over the back side of the substrate 102C through the patterned photoresist layer 105 to etch primary curvy side surface S1′ into a vertical side surface S1 and form the recess 108. The respective process is illustrated as process S156 in the process flow shown in FIG. 22. The curvy side surface S2 of the recess 108 remains the same since it is covered by the patterned photoresist layer 105 without exposing to the second etching process. Accordingly, the recess 108 shown in FIG. 14 includes a vertical side surface S1 adjacent to the optical coupler 107 (i.e., at an end of the optical coupler 107) and a curvy side surface S2, which is non-parallel to the vertical side surface S1 and opposite to the vertical side surface S1.

Then, referring to FIG. 15, the patterned photoresist layer 105 is removed, and a photonic die 101 is substantially formed. Accordingly, the vertical side surface S1 of the recess 108 can be seen as an interfacing facet (i.e., a first facet S1) for being optically coupled to the optical coupler 107, and the curvy side surface S2 can be seen as a reflecting facet (i.e., a second facet S2) for reflecting light to or from the optical coupler 107. The recess 108 is asymmetrical and includes the first facet S1 that is substantially perpendicular to a longitudinal axis A1 of the optical coupler 107 (i.e., the longitudinal axis A1 of the waveguide 104), and the second facet S2 opposite to the first facet S1 is non-perpendicular to the longitudinal axis A1 of the optical coupler 107. In the present embodiment, the recess 108 may extend from a back side BS of the photonic die 101 toward a front side FS of the photonic die 101. The dielectric material 126 laterally encapsulate the electronic die 122 and overlap with the recess 108 from a top view.

In some embodiments, the second facet S2 of the recess 108 is a concave curvy surface. The profile of the curvy second facet S2 of the recess 108 may be characterized as having an angle θ1 as illustrated in FIG. 14. The angle θ1 may be in a range from about 30 degrees to about 60 degrees. In the present embodiment, the angle θ1 may be about 45 degrees. The angle θ1 as illustrated in FIG. 14 is measured as the angle between a tangent line to the curvy side surface S2 and a horizontal plane parallel to a top surface of the dielectric material 126. The curvature of the curvy side surface S2 may be in a range from about 100 μm to about 800 μm. For exemplary dimensions of the recess 108, the width (or diameter) W1 of recess 108 is in a range from about 19 μm to about 23 μm, and the depth D1 of recess 108 is in a range from about 7 μm to about 8 μm. Accordingly, an aspect ratio of the recess (e.g., W1/D1) 108 may be in a range from about 2.38:1 to about 3.28:1. If the aspect ratio of the recess 108 is greater than 3.28:1, the depth D1 may not be deep enough for light from and/or to the optical coupler 108 to be reflected upward by the second facet S2. If the aspect ratio of the recess 108 is smaller than 2.38:1, the second facet S2 may be approximate to a vertical surface for reflecting light from and/or to the optical coupler 108 upward.

The term “about” or “substantially” can be used to include any numerical value that can vary without changing the basic function of that value. When used with a range, “about” or “substantially” also discloses the range defined by the absolute values of the two endpoints, e.g., “about 2 to about 4” also discloses the range “from 2 to 4”, which may include end points of “2” and “4”. The term “about” or “substantially” may refer to plus or minus 10% of the indicated number.

Then, referring to FIG. 16, a plurality of conductive connectors 132 are disposed over the back side BS of the photonic die 101. In the embodiment, the conductive connectors 132 are formed on a plurality of conductive pads 128 to form a photonic package 100, in accordance with some embodiments. The conductive connectors 132 may be ball grid array (BGA) connectors, solder balls, metal pillars, controlled collapse chip connection (C4) bumps, micro bumps, electroless nickel-electroless palladium-immersion gold technique (ENEPIG) formed bumps, or the like. The conductive connectors 132 may include a conductive material such as solder, copper, aluminum, gold, nickel, silver, palladium, tin, the like, or a combination thereof. In some embodiments, the conductive connectors 132 are formed by initially forming a layer of solder through such commonly used methods such as evaporation, electroplating, printing, solder transfer, ball placement, or the like. Once a layer of solder has been formed on the structure, a reflow may be performed in order to shape the material into the desired bump shapes. In another embodiment, the conductive connectors 132 are metal pillars (such as a copper pillar) formed by a sputtering, printing, electro plating, electroless plating, CVD, or the like. The metal pillars may be solder free and have substantially vertical sidewalls. In some embodiments, a metal cap layer (not shown) is formed on the top of the conductive connectors 132. The metal cap layer may include nickel, tin, tin-lead, gold, silver, palladium, indium, nickel-palladium-gold, nickel-gold, the like, or a combination thereof and may be formed by a plating process.

In some embodiments, a plurality of photonic packages 100 may be formed on a single substrate 102C and then singulated to form a plurality of individual photonic packages 100 such as the photonic package 100 shown in FIG. 16. In embodiments such as this, the dielectric materials 130, 115, 126, and the optical support 125 may extend into a scribe region that is removed during singulation process. The singulation process may be performed using a suitable technique, such as using a saw, laser, the like, or a combination thereof. The photonic package 100 described herein allows for optical communication with an optical fiber 210, shown below for FIG. 17. In the structure of the photonic package 100, the photonic die 101 includes the optical coupler 107 and the recess 108 is aligned with the optical coupler 107. The electronic die 120 is disposed over the front side FS of the photonic die 101 while an optical device (e.g., the optical device 200 shown in FIG. 17) is disposed over the back side BS of the photonic die 101 and is aligned with the recess 108.

FIG. 17 illustrates a cross-sectional view of a photonic system 10 in accordance with some embodiments. In some embodiments, an optical device 200 is bonded to the back side BS of the photonic die 101 to form a photonic system 10 as shown in FIG. 17. In some embodiments, the photonic system 10 may include one or more photonic packages 100 disposed on a package substrate (not shown) and one or more semiconductor devices (not shown) bonded to the package substrate. The photonic package 100 may be similar to those described in FIG. 16. For purpose of clarity and simplicity, detail description of same or similar features may be omitted, and the same or similar reference numbers denote the same or like components. In some embodiments, the photonic package 100 facilitates optical communication between the external optical device 200, other semiconductor devices, optical networks, or the like. In this manner, the photonic system 10 allows for interfacing with one or more optical fibers 210 of the optical device 200. The optical device 200 may be an optical transmitter or receiver, such as a chip, optical fiber, or other component, which is configured to transmit and/or receive an optical signal along an optical communication path P1. The photonic package 100 is configured to interact with the optical transmitter or receiver through the optical communication path P1. In some embodiments, the photonic package 100 can include circuitry or other structures that can generate optical signals, detect optical signals, analyze optical signals, modify optical signals, transfer optical signals, and/or transform optical signals to electrical signals (or vice versa); thereby enabling communication and/or signal processing between the photonic package 100 and the optical device 200.

In some embodiments, the optical device 200 includes an external optical fiber (or waveguide) 210 that includes a fiber connector 220, and a turning mirror 222. The optical device 200 includes a fiber array unit (FAU), or the like. The optical fiber 210 contains an array of fiber elements or waveguides arranged approximately parallel to a longitudinal axis A1 of the optical coupler 107. That is, a longitudinal axis of the optical fiber 210 is parallel to a longitudinal axis A1 of the optical coupler 107. The fiber connector 220 may or may not include an array of lens elements, one for each fiber element, and also includes the turning mirrors 222 to redirect light normal to the surface and into the optical fiber 210. The fiber connector 220 may or may not include an array of lens elements, one for each fiber element. The housing of the fiber connector 220 can be fabricated from low-cost injection-molded plastic or lithographically patterned using a semiconductor substrate, such as a Si optical bench. In some embodiments, the turning mirror 222 may be configured as having an angle θ2 as illustrated in FIG. 17. The angle θ2 may be in a range from about 30 degrees to about 60 degrees. In the present embodiment, the angle θ2 may be about 45 degrees. The angle θ2 as illustrated in FIG. 17 is measured as the angle between a reflecting surface of the turning mirror and a horizontal plane. Furthermore, mechanical alignment features (not shown) can also be fabricated on the back surface BS to facilitate passive alignment to the optical fiber 210 and/or the recess 108. The angle θ2 of the turning mirror 222 may be adjusted and tuned according to dimensions of the recess 108 and/or positions of the optical fiber 210.

The optical fiber 210 may be secured by a fiber holder (not shown) or similar structure, and may be attached to a package substrate where the photonic package 100 is mounted by an optical glue or the like. In other embodiment, the optical fiber 210 and the fiber connector 220 can both be attached to the photonic package 100. In some embodiments, alignment marks for the aligning of optical device 200 may be formed in the photonic package 100, for example, on the back side of the photonic die 101, dielectric material 130, or in another layer. In some embodiments, the optical fiber 210 is actively aligned to the optical coupler 107 by adjusting the position of the optical fiber 210 while monitoring the signal strength as detected by the photonic package 100. The use of the dielectric layer 130 may reduce optical loss of the coupling between the optical fiber 210 and the optical coupler 107.

In some embodiments, the photonic package 100 receives optical signals from the optical fiber 210 (e.g., at the optical coupler 107) which are detected using suitable photonic components 106. One or more electronic dies 122 in the photonic package 100 may then generate corresponding electrical signals based on the optical signals. These electrical signals may then be transmitted to a semiconductor device through the package substrate. In some embodiments, the semiconductor device generates electrical signals that may be transmitted to one or more electronic dies 122 of a photonic package 100 through the package substrate. The electronic dies 122 may then generate optical signals using suitable photonic components 106 and couple these optical signals into the optical fiber 210 (e.g., using the optical coupler 107). In some embodiments, the semiconductor device controls the electronic dies 122 of the photonic package 100. In this manner, in some embodiments, the photonic package 100 may be considered an “optical input/output (I/O) module” for the photonic system 10. Use of photonic packages 100 as described herein may reduce the size or cost of a photonic system 10 while providing high-speed optical communication.

In some embodiments, the optical coupler 107 includes an edge coupler, which is formed that allow optical signals and/or optical power to be transferred horizontally. Accordingly, optical signals and/or optical power transmitted between the edge-mounted optical fiber 210 and the edge coupler 107 may be transmitted through the optical communication path P1. For example, Optical signals may be transmitted from the edge coupler 107 to the optical fiber 210 by passing through the dielectric layer 109, the first facet S1 of the recess 108, reflected/redirected by the second facet S2 toward the turning mirror 222, then be reflected/redirected again by the turning mirror 222 and then be transmitted into the optical fiber 210 mounted on the back side BS of the photonic die 101. Optical signals may also be transmitted from the optical fiber 210 to the edge coupler 107 through the optical communication path P1 in reverse order and be transmitted into the waveguides 104, wherein the optical signals may be detected by a photonic component 106 including a photodetector and transmitted as electrical signals into the electronic die 122. Optical signals generated within the waveguides 104 by a photonic component 106 including a modulator may similarly be transmitted from the edge coupler 107 to the optical fiber 210 mounted on the back side BS of the photonic die 101.

In some embodiments, a reflective layer 1081 may be formed to cover the curvy side surface S2 as shown in FIG. 17. The concave reflective layer 1081 conformally covers the curvy side surface S2 of the recess 108 and faces the optical coupler 107 to reflect the optical signals to be transmitted to/from the optical coupler 107 without being absorbed, in accordance with some embodiments. FIG. 17 shows that the optical signals are reflected by the second facet S2 and the reflective layer 1081 (if exist) of the recess 108 and is redirected toward (a center of) the turning mirror 222. The reflective layer 1081 may be deposited over the second facet S2 after the recess 108 is formed. Reflectivity is defined as a fraction of light being reflected. A reflective material can reflect a fraction (or percentage) of light (i.e., optical signals), such as 5%, 10%, 50% or 80%. The higher the reflectivity of the material, the higher percentage of the light is reflected. Most of the metals have relatively high reflectivity. In some embodiments, the reflective materials for the applications described above are metals. Examples of reflective metals that can be used for such application include, but are not limited to, tungsten (W), aluminum (Al), and copper (Cu), zinc (Zn), gold (Au), silver (Ag), titanium (Ti), tantalum (Ta), chromium (Cr), tin (Sn), cobalt (Co), nickel (Ni), any combination thereof, or the like. The reflective material can also be a metal-containing film or an alloy that is made of two or more metals.

Non-metal (or non-metallic) materials that are reflective may also be used in the reflective layer 1081. For example, polytetrafluorethylene (PTFE) is a polymer that has high reflectivity. In some embodiments, an adhesion layer (or adhesion-promoting layer) (not shown) is deposited under the reflective layer 1081 to promote adhesion between the reflective layer and second facet S2, which is defined by dielectric materials. For example, if the reflective layer 1081 is made of W, an adhesion layer made of Ti, TiN, Ta, TaN, or a combination of the above-mentioned adhesion-promoting materials can be used. The reflective layer 1081 can be deposited by chemical vapor deposition (CVD), physical vapor deposition (PVD), atomic layer deposition (ALD), plating, spin-on or other applicable methods. For example, W can be deposited by CVD, and the adhesion-promoting material for W, such as Ti and TiN, can be deposited by PVD in some embodiments. The disclosure is not limited thereto.

With such configuration, optical signals can be reflected and redirected toward the back side BS of the photonic die 101 by the second facet S2 of the recess 108, so that the optical device 200 with the turning mirror 222 can be mounted on the back side BS of the photonic die 101 instead of edge-mounted on an edge or sidewall of the photonic package 100. Accordingly, with the configuration of the recess 108, a wafer level optical testing can be realized. In addition, with the configuration of the recess 108, the optical signals is transmitted through the back side BS of the photonic die 101 so that the number of optical input/output (I/O) ports (i.e., the number of optical couplers/waveguides for input/output optical signals) can be significantly increased since the configuration of the I/O ports are no longer constrained at the sidewall of photonic die 101, but can be distributed over the back side BS of photonic die 101. Moreover, forming the recess 108 in the photonic die 101 for redirecting optical signals allows greater design flexibility of a photonic package 100 and/or a photonic system 10 and shallower etching depth of the recess 108, which results in lowering production cost of a photonic package 100 and/or a photonic system 10.

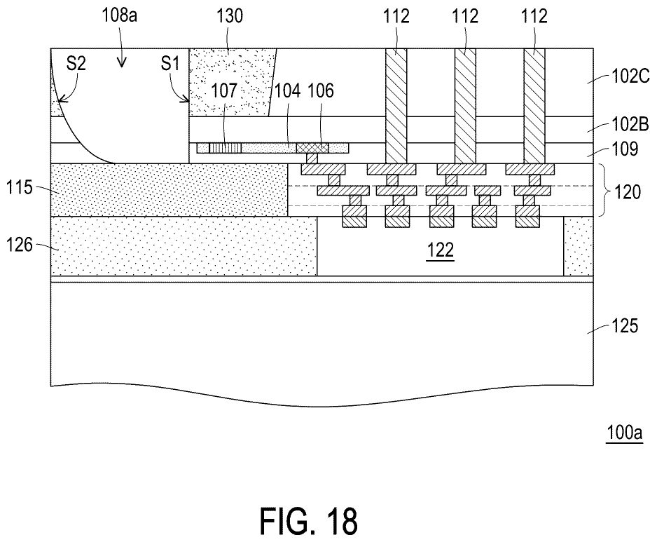

FIG. 18 illustrates a cross-sectional view of an intermediate stage of forming a photonic package in accordance with some embodiments. It is noted that the photonic package 100a shown in FIG. 18 contains many features same as or similar to the photonic packages disclosed in the previous embodiments. For purpose of clarity and simplicity, detail description of same or similar features may be omitted, and the same or similar reference numbers denote the same or like components.

Referring to FIG. 18, in the present embodiment, the recess 108a is extended at least through the dielectric layer 109 so that the facets (e.g., the first facet S1 and the second facet S2) can face the optical coupler 107. To be more specific, in the embodiment, the recess 108a is extended through the dielectric material 130 of the substrate 102C, the oxide layer 102B, and the dielectric layer 109 covering the photonic layer including photonic components 106, waveguides 104, and optical couplers 107, but not extended through the dielectric material 115 of the redistribution structure 120. In some embodiments, the recess 108a may be extended to an upper portion of the dielectric material 115 but not extended all the way through the dielectric material 115 of the redistribution structure 120. The disclosure is not limited thereto.

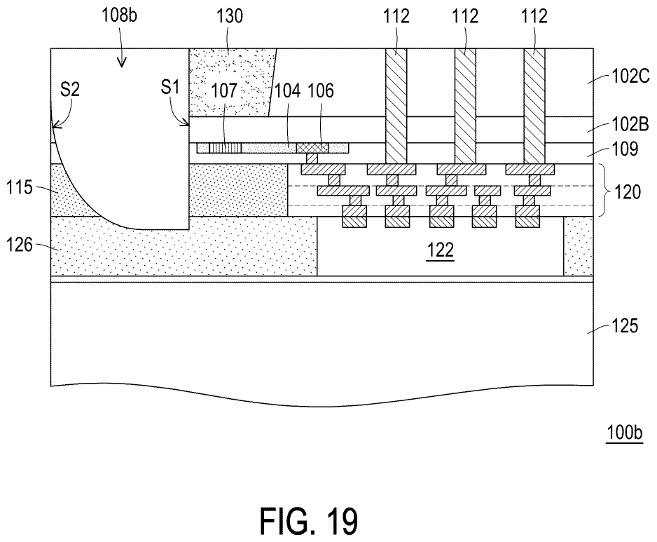

FIG. 19 illustrates a cross-sectional view of an intermediate stage of forming a photonic package in accordance with some embodiments. It is noted that the photonic package 100b shown in FIG. 19 contains many features same as or similar to the photonic packages disclosed in the previous embodiments. For purpose of clarity and simplicity, detail description of same or similar features may be omitted, and the same or similar reference numbers denote the same or like components.

Referring to FIG. 19, in the present embodiment, the recess 108b is extended to an upper portion of the dielectric material 126 that laterally encapsulates the electronic die 122. To be more specific, in the embodiment, the recess 108b is extended through the dielectric material 130 of the substrate 102C, the oxide layer 102B, and the dielectric layer 109 covering the photonic layer including photonic components 106, waveguides 104, and optical couplers 107, the dielectric material 115 of the redistribution structure 120, but not extended through the dielectric material 126 laterally encapsulating the electronic die 122. In some embodiments, the recess 108b may be extended to the upper portion of the dielectric material 126 but not extended all the way through the dielectric material 126. The disclosure is not limited thereto.

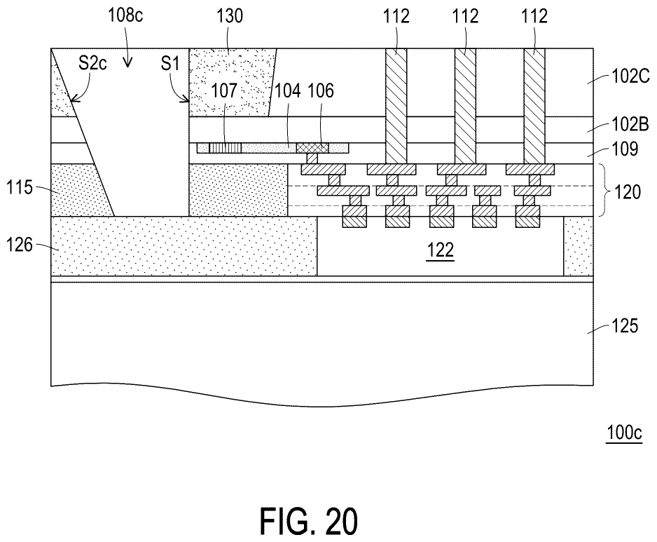

FIG. 20 illustrates a cross-sectional view of an intermediate stage of forming a photonic package in accordance with some embodiments. It is noted that the photonic package 100c shown in FIG. 20 contains many features same as or similar to the photonic packages disclosed in the previous embodiments. For purpose of clarity and simplicity, detail description of same or similar features may be omitted, and the same or similar reference numbers denote the same or like components.

Referring to FIG. 20, in accordance with some embodiments of the disclosure, the second facet S2c of the recess 108c is an inclined planar surface. The second facet S2c is inclined with respect to a horizontal plane that is parallel to an upper surface (interfacing surface) of the dielectric material 126. An angle is included between the inclined planar surface of the second facet S2c and the horizontal plane parallel to the upper surface of the dielectric material 126. The angle of the second facet S2c may be in a range from about 30 degrees to about 60 degrees. In the present embodiment, the angle of the second facet S2c may be about 45 degrees. In the present embodiment, the recess 108c is extended through the dielectric material 115 of the redistribution structure 120 to the upper surface of the dielectric material 126 that laterally encapsulates the electronic die 122. To be more specific, in the embodiment, the recess 108b is extended through the dielectric material 130 of the substrate 102C, the oxide layer 102B, and the dielectric layer 109 covering the photonic layer including photonic components 106, waveguides 104, and optical couplers 107, the dielectric material 115 of the redistribution structure 120, but not extended to the dielectric material 126 laterally encapsulating the electronic die 122. In other embodiments, the recess 108c may be extended to the upper surface of the dielectric material 126 but not extended all the way through the dielectric material 126. The disclosure is not limited thereto. In other embodiments, the recess 108c may be extended to the dielectric material 115 of the redistribution structure 120 but not extended all the way through the dielectric material 115. The disclosure is not limited thereto.

Based on the above discussions, it can be seen that the present disclosure offers various advantages. It is understood, however, that not all advantages are necessarily discussed herein, and other embodiments may offer different advantages, and that no particular advantage is required for all embodiments.

In above-illustrated embodiments, some processes and features are discussed in accordance with some embodiments of the present disclosure to form a three-dimensional (3D) package. Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

In accordance with some embodiments of the disclosure, a photonic package includes a photonic die and an electronic die. The photonic die includes an optical coupler and a recess extending from a back side of the photonic die toward a front side of the photonic die, wherein the recess includes a first facet at an end of the optical coupler and a second facet opposite to the first facet and non-parallel to the first facet for reflecting light to or from the optical coupler. The electronic die is disposed over the front side of the photonic die. In an embodiment, the second facet is a concave curvy surface. In an embodiment, the first facet is substantially perpendicular to a longitudinal axis of the optical coupler, and the second facet is non-perpendicular to the longitudinal axis of the optical coupler. In an embodiment, the photonic package further includes a dielectric material laterally encapsulate the electronic die and overlap with the recess from a top view. In an embodiment, the recess extended to an upper portion of the dielectric material. In an embodiment, the photonic package further includes an optional support disposed over the electronic die. In an embodiment, the photonic package further includes a plurality of conductive connectors disposed over the back side of the photonic die. In an embodiment, the photonic package further includes a plurality of through vias extending through a substrate of the photonic die and electrically connected to the electronic die. In an embodiment, the photonic package further includes a reflective layer covering the second facet. In an embodiment, the optical coupler comprises an edge coupler.

In accordance with some embodiments of the disclosure, a photonic system includes a photonic die, an electronic die, and an optical device. The photonic die includes an optical coupler and a recess aligning with the optical coupler, wherein the recess includes a vertical side surface adjacent to the optical coupler and a curvy side surface opposite to the vertical side surface for reflecting light to or from the optical coupler. The electronic die is disposed over a front side of the photonic die. The optical device is disposed over a back side of the photonic die and aligning with the recess. In an embodiment, the optical device comprises an optical fiber and a turning mirror to redirect light normal into the optical fiber. In an embodiment, a longitudinal axis of the optical fiber is parallel to a longitudinal axis of the optical coupler. In an embodiment, the photonic system further includes a dielectric material laterally encapsulate the electronic die and overlap with the recess from a top view. In an embodiment, the photonic system further includes an optional support disposed over the electronic die. In an embodiment, the photonic system further includes a plurality of conductive connectors disposed over the back side of the photonic die.

In accordance with some embodiments of the disclosure, a manufacturing method of a photonic system includes: forming an optical coupler over a substrate; forming a redistribution structure over the optical coupler; bonding an electronic die over the redistribution structure; bonding an optional support over the electronic die; and performing an etching process over a back side of the substrate to form a recess, wherein the recess includes a vertical side surface adjacent to the optical coupler and a curvy side surface non-parallel and opposite to and the vertical side surface. In an embodiment, performing the etching process over the back side of the substrate to form the recess includes: performing a first etching process over the back side of the substrate to form a primary recess, wherein the primary recess includes a primary curvy side surface adjacent to the optical coupler and the curvy side surface opposite to and the primary curvy side; and providing a patterned photoresist layer over the back side of the substrate, wherein the patterned photoresist layer covers the curvy side surface and reveals the primary curvy side surface; and performing a second etching process over the back side of the substrate through the patterned photoresist layer to form the vertical side surface of the recess. In an embodiment, the manufacturing method of the photonic system further includes bonding an optical device over the back side of the substrate, wherein the optical device is aligned with the recess. In an embodiment, the manufacturing method of the photonic system further includes bonding a plurality of conductive connectors over the back side of the substrate.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A photonic package, comprising:
a photonic die comprising an optical coupler and a recess extending from a back side of the photonic die toward a front side of the photonic die, wherein the recess comprises a first facet at an end of the optical coupler and a second facet opposite to the first facet and non-parallel to the first facet for reflecting light to or from the optical coupler; and
an electronic die disposed over the front side of the photonic die.

2. The photonic package as claimed in claim 1, wherein the second facet is a concave curvy surface.

3. The photonic package as claimed in claim 1, wherein the first facet is substantially perpendicular to a longitudinal axis of the optical coupler, and the second facet is non-perpendicular to the longitudinal axis of the optical coupler.

4. The photonic package as claimed in claim 1, further comprising a dielectric material laterally encapsulate the electronic die and overlap with the recess from a top view.

5. The photonic package as claimed in claim 4, wherein the recess extended to an upper portion of the dielectric material.

6. The photonic package as claimed in claim 1, further comprising an optional support disposed over the electronic die.

7. The photonic package as claimed in claim 1, further comprising a plurality of conductive connectors disposed over the back side of the photonic die.

8. The photonic package as claimed in claim 1, further comprising a plurality of through vias extending through a substrate of the photonic die and electrically connected to the electronic die.

9. The photonic package as claimed in claim 1, further comprising a reflective layer covering the second facet.

10. The photonic package as claimed in claim 1, wherein the optical coupler comprises an edge coupler.

11. A photonic system, comprising:
a photonic die comprising an optical coupler and a recess aligning with the optical coupler, wherein the recess comprises a vertical side surface adjacent to the optical coupler and a curvy side surface opposite to the vertical side surface for reflecting light to or from the optical coupler;
an electronic die disposed over a front side of the photonic die; and
an optical device disposed over a back side of the photonic die and aligning with the recess.

12. The photonic system as claimed in claim 11, wherein the optical device comprises an optical fiber and a turning mirror to redirect light normal into the optical fiber.

13. The photonic system as claimed in claim 12, wherein a longitudinal axis of the optical fiber is parallel to a longitudinal axis of the optical coupler.

14. The photonic system as claimed in claim 11, further comprising a dielectric material laterally encapsulate the electronic die and overlap with the recess from a top view.

15. The photonic system as claimed in claim 11, further comprising an optional support disposed over the electronic die.

16. The photonic system as claimed in claim 11, further comprising a plurality of conductive connectors disposed over the back side of the photonic die.

17. A manufacturing method of a photonic system, comprising:
forming an optical coupler over a substrate;
forming a redistribution structure over the optical coupler;
bonding an electronic die over the redistribution structure;
bonding an optional support over the electronic die; and
performing an etching process over a back side of the substrate to form a recess, wherein the recess comprises a vertical side surface adjacent to the optical coupler and a curvy side surface non-parallel and opposite to and the vertical side surface.

18. The manufacturing method of the photonic system as claimed in claim 17, wherein performing the etching process over the back side of the substrate to form the recess comprises:
performing a first etching process over the back side of the substrate to form a primary recess, wherein the primary recess comprises a primary curvy side surface adjacent to the optical coupler and the curvy side surface opposite to and the primary curvy side; and
providing a patterned photoresist layer over the back side of the substrate, wherein the patterned photoresist layer covers the curvy side surface and reveals the primary curvy side surface; and
performing a second etching process over the back side of the substrate through the patterned photoresist layer to form the vertical side surface of the recess.

19. The manufacturing method of the photonic system as claimed in claim 17, further comprising bonding an optical device over the back side of the substrate, wherein the optical device is aligned with the recess.

20. The manufacturing method of the photonic system as claimed in claim 17, further comprising bonding a plurality of conductive connectors over the back side of the substrate.
